(19) United States
(12) Patent Application Publication
(10) Pub. No.: US 2023/0165007 A1
(43) Pub. Date: May 25, 2023

(54) SEMICONDUCTOR MEMORY DEVICE AND ELECTRONIC SYSTEM INCLUDING THE SAME

(71) Applicant: SAMSUNG ELECTRONICS CO., LTD., SUWON-SI (KR)

(72) Inventors: Yun Sun JANG, Seoul (KR); Moo Rym CHOI, Yongin-si (KR); Jung Tae SUNG, Seoul (KR)

(21) Appl. No.: 17/951,337

(22) Filed: Sep. 23, 2022

(30) Foreign Application Priority Data
Nov. 24, 2021 (KR) 10-2021-0163364

(51) Int. Cl. H01L 27/11573; H01L 23/522; H01L 23/528; H01L 27/11582; H01L 27/1157; H01L 27/11565; G11C 16/04

(52) U.S. Cl. CPC H01L 27/11573; H01L 23/5226; H01L 23/5283; H01L 27/11582; H01L 27/1157; H01L 27/11565; G11C 16/0483

(57) ABSTRACT

A semiconductor memory device has a peripheral logic structure including a peripheral logic substrate and a peripheral logic insulating film on the peripheral logic substrate. A cell array structure includes a cell substrate and a source structure that are sequentially stacked on the peripheral logic structure. A bypass via electrically connects the cell substrate and the peripheral logic substrate. The bypass via has a linear shape extending in at least one of first and second directions on the cell substrate. The first and second directions are parallel to an upper surface of the cell substrate.

### CROSS-REFERENCE TO RELATED APPLICATION

This application claims priority under 35 U.S.C. § 119 to Korean Patent Application No. 10-2021-0163364, filed on Nov. 24, 2021 in the Korean Intellectual Property Office, the disclosure of which is incorporated by reference in its entirety herein.

### TECHNICAL FIELD

The present disclosure relates to a semiconductor device and an electronic system including the same,

### DISCUSSION OF RELATED ART

There has been a demand for increasing the integration density of semiconductor memory devices to provide a high performance and low price. The integration density is one of the most important price-determining factors for semiconductor memory devices.

The integration density of a conventional two-dimensional (2D) or planar semiconductor memory device is determined by the area occupied by unit memory cells and is thus considerably affected by the level of fine pattern-forming technology. However, as expensive equipment is needed for the miniaturization of patterns, there is a limit in increasing the integration density of a 2D semiconductor memory device. Accordingly, a three-dimensional (3D) semiconductor device has been suggested in which memory cells are arranged three-dimensionally to provide an increased integration density.

### SUMMARY

Aspects of the present disclosure provide a semiconductor memory device capable of preventing arching and providing sufficient space for peripheral transistors, a lower wiring structure, and/or upper wires to be arranged.

Aspects of the present disclosure also provide an electronic system including a semiconductor memory device capable of preventing arching and providing sufficient space for peripheral transistors, a lower wiring structure, and/or upper wires to be arranged.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an embodiment of the present disclosure, a semiconductor memory device has a peripheral logic structure including a peripheral logic substrate and a peripheral logic insulating film on the peripheral logic substrate. A cell array structure includes a cell substrate and a source structure that are sequentially stacked on the peripheral logic structure. A bypass via electrically connects the cell substrate and the peripheral logic substrate. The bypass via has a linear shape extending in at least one of first and second directions on the cell substrate. The first and second directions are parallel to an upper surface of the cell substrate.

According to an embodiment of the present disclosure, a semiconductor memory device has a peripheral logic structure including a peripheral logic substrate and a peripheral transistor on the peripheral logic substrate. A cell substrate and a source structure are sequentially stacked on the peripheral logic structure. A first stack structure includes a plurality of first gate electrodes that are stacked on the source structure. A first bypass via and a second bypass via electrically connect the cell substrate and the peripheral logic substrate. A width in a first direction of the first bypass via differs from a width in the first direction of the second bypass via.

According to an embodiment of the present disclosure, an electronic system includes a main substrate. A semiconductor memory device is on the main substrate. A controller is on the main substrate. The controller is electrically connected to the semiconductor memory device. The semiconductor memory device includes a peripheral logic substrate. A peripheral transistor is electrically connected to the controller on the peripheral logic substrate. A peripheral logic insulating film covers the peripheral transistors. A cell substrate is on the peripheral logic insulating film. A source structure is on the cell substrate. A stack structure is on the source structure. The stack structure includes a plurality of gate electrodes that are stacked. A channel structure penetrates the stack structure. A first bypass via and a second bypass via electrically connect the cell substrate and the peripheral logic substrate. The first bypass via and the second bypass via have a linear shape extending in at least one of first and second directions on the cell substrate. The first and second directions are parallel to an upper surface of the cell substrate.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a block diagram of a semiconductor memory device according to an embodiment of the present disclosure;

FIG. 2 is a perspective view of a semiconductor memory device according to an embodiment of the present disclosure;

FIG. 3 is a circuit diagram of a semiconductor memory device according to an embodiment of the present disclosure;

FIG. 4 is a plan view of a cell array structure of FIG. 2 according to an embodiment of the present disclosure;

FIG. 5 is a plan view of a mat of FIG. 4 according to an embodiment of the present disclosure;

FIG. 6 illustrates a stack structure of FIG. 5 according to an embodiment of the to present disclosure;

FIG. 7 is a cross-sectional view taken along line A-A′ of FIG. 5 according to an embodiment of the present disclosure;

FIG. 8 is an enlarged cross-sectional view of an area S1 of FIG. 7 according to an embodiment of the present disclosure;

FIG. 9 is a perspective view illustrating bypass vias of FIG. 5 according to an embodiment of the present disclosure;

FIGS. 10 through 17 are plan views illustrating semiconductor memory devices according to some embodiments of the present disclosure;

FIG. 18 is a cross-sectional view taken along line A-A′ of FIG. 5 of a semiconductor memory device according to an embodiment of the present disclosure;

FIG. 19 is an enlarged cross-sectional view of an area S2 of FIG. 18 according to an embodiment of the present disclosure;

FIG. 20 is a cross-sectional view taken along line A-A′ of FIG. 5 of a semiconductor memory device according to an embodiment of the present disclosure;

FIG. 21 is a perspective view of an electronic system including a semiconductor memory device according to an embodiment of the present disclosure;

FIG. 22 is a perspective view of an electronic system including a semiconductor memory device according to an embodiment of the present disclosure; and

FIG. 23 is a cross-sectional view taken along line of FIG. 22 according to an embodiment of the present disclosure.

### DETAILED DESCRIPTION OF EMBODIMENTS

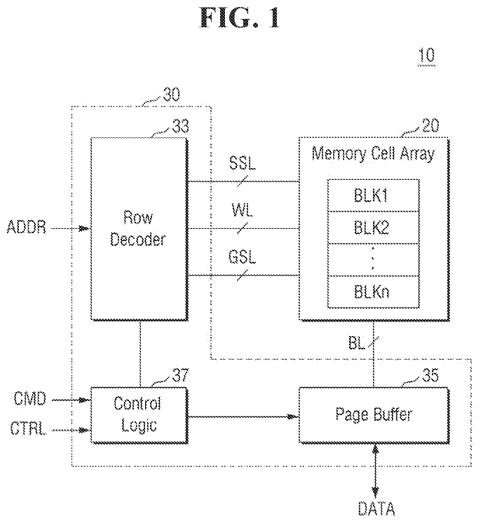

FIG. 1 is a block diagram of a semiconductor memory device according to some embodiments of the present disclosure.

Referring to FIG. 1, a semiconductor memory device 10 may include a memory cell array 20 and a peripheral circuit 30.

The memory cell array 20 may include a plurality of first through n-th memory cell blocks BLK1 through BLKn. Each of the first through n-th memory cell blocks BLK1 through BLKn may include a plurality of memory cells. Each of the first through nth memory cell blocks BLK1 through BLKn may be connected to the peripheral circuit 30 through bitlines BL, wordlines WL, one or more string selection lines SSL, and one or more ground selection lines GSL.

In an embodiment, the first through n-th memory cell blocks BLK1 through BLKn may be connected to a row decoder 33 through the wordlines WL, the string selection lines SSL, and the ground selection lines GSL. The first through nth memory cell blocks BLK1 through BLKn may be connected to a page buffer 35 through the bitlines BL.

The peripheral circuit 30 may receive an address ADDR, a command CMD, and a control signal CTRL from outside the semiconductor memory device 10 and may exchange data “DATA” with an external device outside the semiconductor memory device 10. In an embodiment, the peripheral circuit 30 may include a control logic 37, the row decoder 33, and the page buffer 35.

In an embodiment, the peripheral circuit 30 may further include various sub-circuits such as an input/output circuit, a voltage generating circuit for generating various voltages necessary for the operation of the semiconductor memory device 10 and an error correction circuit for correcting error in data “DATA” read from the memory cell array 20.

The control logic 37 may be connected to the row decoder 33, an input/output circuit, and the voltage generating circuit. The control logic 37 may control the general operation of the semiconductor memory device 10. The control logic 37 may generate various internal control signals for use in the semiconductor memory device 10 in response to the control signal CTRL. For example, in an embodiment, the control logic 37 may control the levels of voltages provided to the wordlines WL and the bitlines BL during a memory operation such as a program operation or an erase operation.

The row decoder 33 may select at least one of the first through n-th memory cell blocks BLK1 through BLKn in response to the address ADDR and may select at least one of the wordlines WL, the string selection lines SSL, and the ground selection lines GSL of the selected memory cell block. Also, the row decoder 33 may transmit a voltage for performing a memory operation to the selected wordline(s) WL of the selected memory cell block.

The page buffer 35 may be connected to the memory cell array 20 via the bitlines BL. The page buffer 35 may operate as a write driver or a sense amplifier. For example, in an embodiment, during a program operation, the page buffer 35 may operate as a write driver and may apply a voltage corresponding to data “DATA” to be written to the memory cell array 20 to the bitlines BL. During a read operation, the page buffer 35 may operate as a sense amplifier and may sense data “DATA” stored in the memory cell array 20.

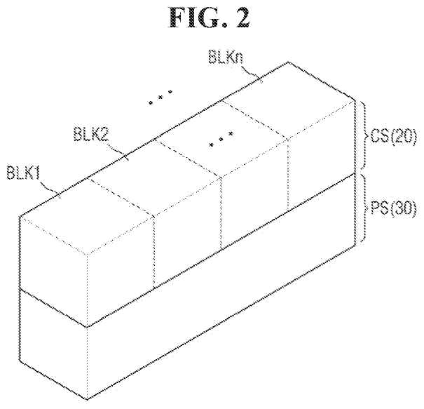

FIG. 2 is a perspective view of a semiconductor memory device according to an embodiment of the present disclosure.

Referring to FIG. 2. the semiconductor memory device may include a peripheral logic structure PS and a cell array structure CS.

The cell array structure CS may be stacked on the peripheral logic structure PS. For example, the peripheral logic structure PS and the cell array structure CS may overlap with each other in a plan view. In an embodiment, the semiconductor memory device may have a Cell-over-Peri (COP) structure.

For example, the cell array structure CS may include the memory cell array 20 of FIG. 1. The peripheral logic structure PS may include the peripheral circuit 30 of FIG. 1.

The cell array structure CS may include a plurality of first through n-th memory cell blocks BLK1 through BLKn, which are disposed on the peripheral logic structure PS.

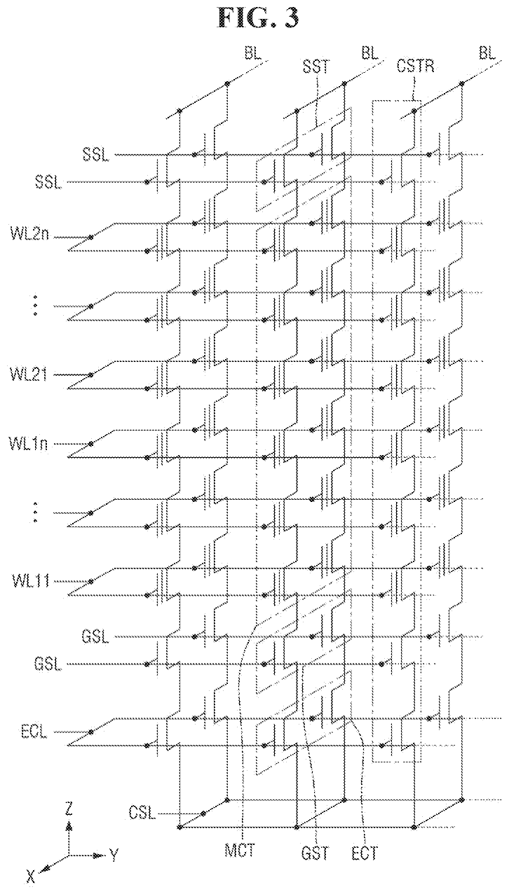

FIG. 3 is a circuit diagram of a semiconductor memory device according to some embodiments of the present disclosure.

Referring to FIG. 3, a memory cell array (see, for example, “20” of FIG. 1) of the semiconductor memory device may include a common source line CSL, bitlines BL, and cell strings CSTR.

The common source line CSL may extend in a first direction X. In some embodiments, a plurality of common source lines CSL may he arranged two-dimensionally. For example, the plurality of common source lines CSL may be spaced apart from one another and may extend in the first direction X. In an embodiment, the same voltage may be applied to the plurality of common source lines CSL. However, embodiments of the present disclosure are not necessarily limited thereto. For example, in an embodiment, different voltages may be applied to the plurality of common source lines CSL so that the plurality of common source lines CSL may be controlled separately.

The bitlines BL may be arranged two-dimensionally. For example, the bitlines BL may be spaced apart from one another and may extend in the first direction X, which intersects a second direction Y. Multiple cell strings CSTR may be connected in parallel to each of the bitlines BL and may be connected in common to the common source line CSL. For example, multiple cell strings CSTR may be disposed between the bitlines BL and the common source line CSL (e.g, in a third direction Z).

Each of the cell strings CSTR may include a ground selection transistor GST, which is connected to one of the common source line CSL, a string selection transistor SST, which is connected to one of the bitlines BL, and a plurality of memory cell transistors MCT, which are disposed between the ground selection transistor GST and the string selection transistor SST (e.g., in the third direction Z). Each of the memory cell transistors MCT may include a data storage element. The ground selection transistor GST, the string selection transistor SST, and the memory cell transistors MCT may be connected in series.

The common source line CSL may be connected in common to the sources of ground selection transistors GST, Ground selection lines GSL, a plurality of wordlines through WL1n and WL21 through WL2n), and string selection lines SSL may be disposed between the common source line CSL and the bitlines BL. The ground selection lines GSL may be used as the gate electrodes of the ground selection transistors GST, the wordlines (WL11 through WL1n and WL21 through WL2n) may be used as the gate electrodes of memory cell transistors MCT, and the string selection lines SSL may be used as the gate electrodes of string selection transistors SST.

In some embodiments, erase control transistors ECT may be disposed between the common source line CSL and the ground selection transistors GST (e.g., in the third direction Z). The common source line CSL may be connected in common to the sources of the erase control transistors ECT. Erase control lines ECL may be disposed between the common source line CSL and the ground selection lines GSL. The erase control lines ECL may be used as the gate electrodes of the erase control transistors ECT. The erase control transistors ECT may cause gate-induced drain leakage (GIDL) and may thus perform an erase operation of the memory cell array.

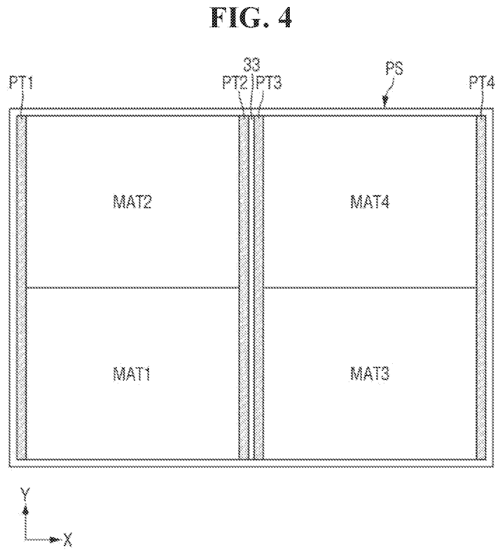

FIG. 4 illustrates the cell array structure of FIG. 2.

Referring to FIG. 4, the cell array structure CS may include a plurality of first through fourth mats MAT1 through MAT4. The first through fourth mats MAT1 through MAT4 may be arranged in the first and second directions X and Y. Each of the first through fourth mats MAT1 through MAT4 may include a plurality of memory blocks (BLK0 through BLKn of FIG. 2).

In some embodiments, a first pass transistor PT1 may be disposed on a first side of each of the first and second mats MAT1 and MAT2, a second pass transistor PT2 may be disposed on an opposite second side of each of the first and second mats MAT1 and MAT2, a third pass transistor PT3 may be disposed on a first of each of the third and fourth mats MAT3 and MAT4, and a fourth pass transistor may be disposed on an opposite second side of each of the third and fourth mats MAT1 and MAT4.

In some embodiments, a row decoder 33 may be disposed between the first and third mats MAT1 and MAT3, which are spaced apart from each other in the first direction X, and between the second and fourth mats MAT2 and MAT4, which are spaced apart from each other in the first direction X. The row decoder 33 may be connected to the wordlines (WL11 through WLin and WL21 through WL2n) of FIG. 3 through the first through fourth pass transistors PT1 through PT4, and when the first through fourth pass transistors PT1 through PT4 are turned on, wordline voltages may be input to the wordlines (WL11 through WL1n and WL21 through WL2n).

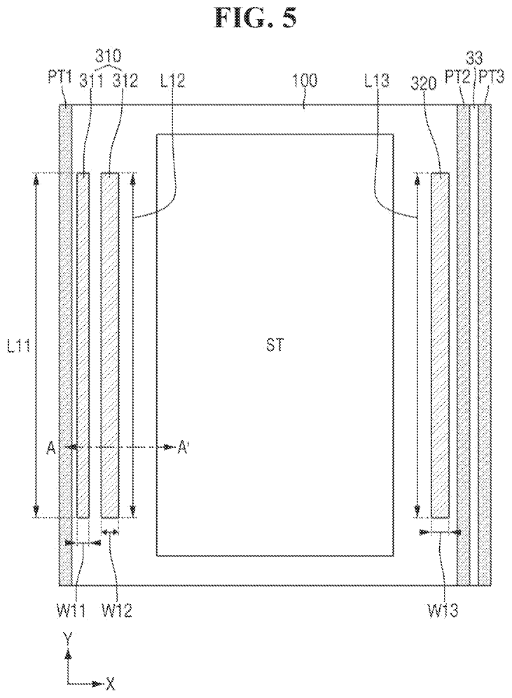

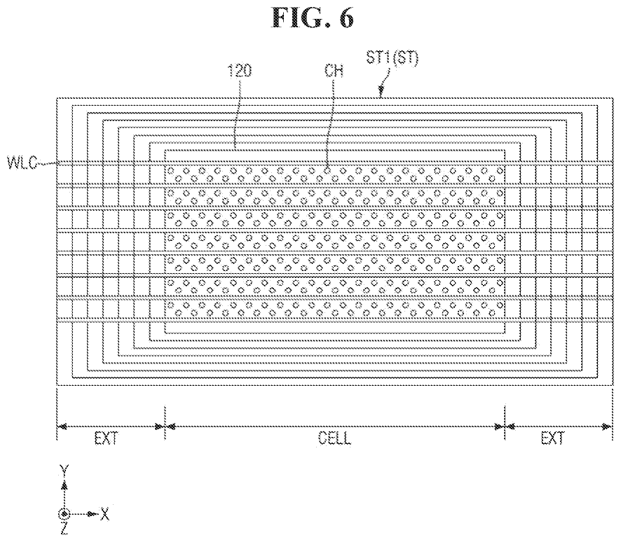

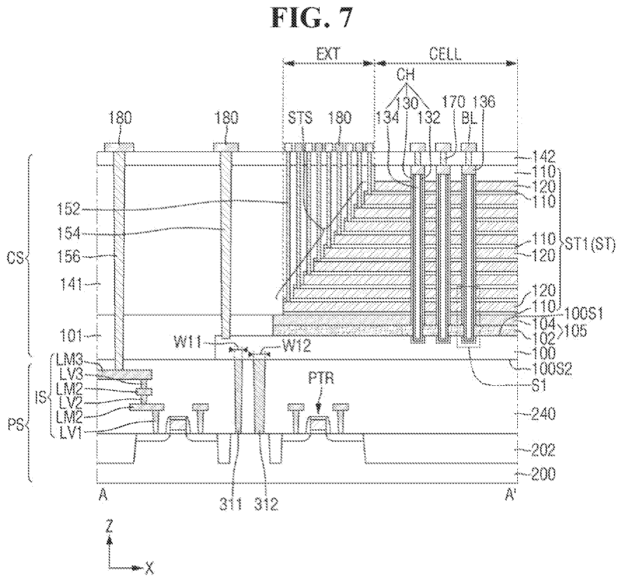

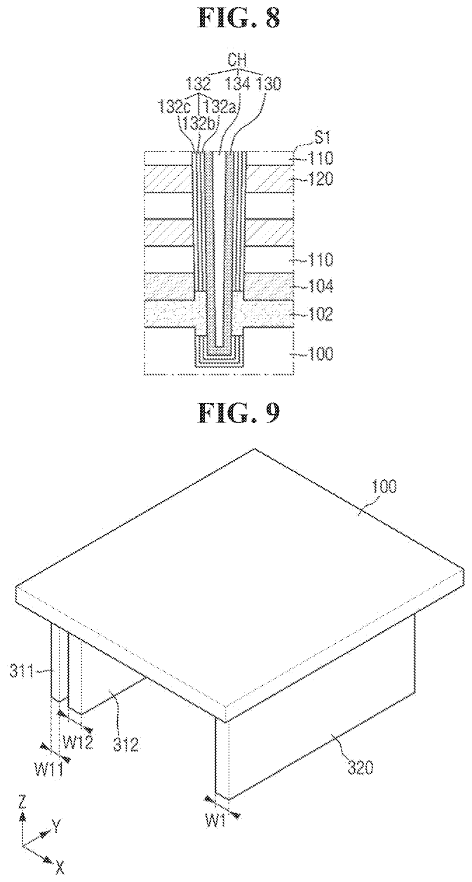

FIG. 5 illustrates a mat of FIG. 4, FIG. 6 illustrates a stack structure of FIG. 5. FIG. 7 is a cross-sectional view taken along line A-A′ of FIG. 5. FIG. 8 is an enlarged cross-sectional view of an area S1 of FIG. 7. FIG. 9 is a perspective view illustrating bypass vias of FIG. 5. FIG. 5 illustrates one of the first through fourth mats MAT1 through MAT4 of FIG. 4. For convenience, FIG. 9 illustrates only a cell substrate 100 and bypass vias 310 and 320.

Referring to FIGS. 5 through 9, the semiconductor memory device may include a cell array structure CS and a peripheral logic structure PS.

The cell array structure CS may include a cell substrate 100, a first source structure 105, and a stack structure ST.

The cell substrate 100 may have first and second surfaces 100S1 and 100S2, which are opposite to each other. The first and second surfaces 100S1 and 100S2 may be opposite to each other in the third direction Z. In an embodiment, the cell substrate 100 may include a semiconductor substrate such as, for example, a silicon substrate, a germanium substrate, or a silicon-germanium substrate. Alternatively, the cell substrate 100 may include a silicon-on-insulator (SOI) substrate or a germanium-on-insulator (GOI) substrate. In some embodiments, the cell substrate 100 may include impurities. For example, the cell substrate 100 may include n-type impurities (e.g., phosphorus (P) or arsenic (As)).

The stack structure ST may be formed on the first surface 100S1 of the cell substrate 100. The stack structure ST may be a first stack structure ST1 including a plurality of first gate electrodes 120 and a plurality of first insulating films 110, which are stacked on the cell substrate 100.

The first gate electrodes 120 and the first insulating films 110 may have a layered structure extending in parallel to the first surface 100S1 of the cell substrate 100. For example, in an embodiment, the first gate electrodes 120 and the first insulating films 110 may extend in the first direction X. However, embodiments of the present disclosure are not necessarily limited thereto. The first gate electrodes 120 and the first insulating films 110 may be alternately stacked on the cell substrate 100. The number of first gate electrodes 120 is not particularly limited, but may vary.

The first gate electrodes 120 may correspond to the erase control line ECL, the ground selection lines GSL, the wordlines (WL11 through WL1n and WL21 through WL2n), and the string selection lines SSL of FIG. 3. In some embodiments, the erase control line ECL may not be provided. Also, in some embodiments, first gate electrodes 120 adjacent to the ground selection lines GSL or to the string selection lines SSL may be dummy gate electrodes.

In an embodiment, the first insulating films 110 may include at least one of, for example, silicon oxide, silicon nitride, and silicon oxynitride. However, embodiments of the present disclosure are not necessarily limited thereto. For example, the first insulating films 110 may include silicon oxide.

The first stack structure ST1 may include a cell region CELL and an extension region EXT. The extension region EXT may be disposed around the cell region CELL. The first gate electrodes 120 may form a staircase structure STS in the extension region EXT. For example, the first gate electrodes 120 may extend by different lengths in the first direction X and/or the second direction Y and may have a step difference with one another.

Block separation structures WLC may extend in the first direction X to cut the first stack structure ST1. The first stack structure ST1 may be cut by a plurality of block separation structures WLC to form a plurality of memory cell blocks (see, for example, “BLK1 through BLKn” of FIG. 1). For example, two adjacent block separation structures WLC may define one memory cell block therebetween. A plurality of channel structures CH may be disposed in each of the memory cell blocks defined by the block isolation structures WLC.

The block separation structures WLC may include an insulating material. For example, the insulating material may fill the block separation structures WLC. In an embodiment, the insulating material may include at least one of, for example, silicon oxide, silicon nitride, and silicon oxynitride. However, embodiments of the present disclosure are not necessarily limited thereto.

The number of channel structures CH arranged in one memory cell block in a zigzag fashion in the second direction Y is not particularly limited, but may vary.

The channel structures CH may be formed in the cell region CELL. The channel structures CH may extend in a vertical direction (e.g., the third direction Z), which intersects the first surface 100S1 of the cell substrate 100, to penetrate the first stack structure ST1. For example, the channel structures CH may have a pillar shape (e.g., a cylindrical shape) extending in the third direction Z. Accordingly, the channel structures CH may intersect the first gate electrodes 120. In some embodiments, the width of the channel structures CH may increase as a distance from the cell substrate 100 increases.

The channel structures CH may include semiconductor patterns 130 and information storage films 132.

The semiconductor patterns 130 may extend in the third direction Z and may penetrate the first stack structure ST1. In an embodiment, the semiconductor patterns 130 may have a cup shape. However, embodiments of the present disclosure are not necessarily limited thereto. For example, the semiconductor patterns 130 may have various shapes such as a cylindrical shape or a rectangular pillar shape. In an embodiment, the semiconductor patterns 130 may include, for example, a semiconductor material such as monocrystalline silicon, polycrystalline silicon, an organic semiconductor, or a carbon nanostructure. However, embodiments of the present disclosure are not necessarily limited thereto.

The information storage films 132 may be interposed between the semiconductor patterns 130 and the first gate electrodes 120. For example, the information storage films 132 may extend along the outer side surfaces of the semiconductor patterns 130. In an embodiment, the information storage films 132 may include at least one of, for example, silicon oxide, silicon nitride, silicon oxynitride, and a high-k material having a larger dielectric constant than silicon oxide. The high-k material may include at least one of, for example, aluminum oxide, hafnium oxide, lanthanum oxide, tantalum oxide, titanium oxide, lanthanum hafnium oxide, lanthanum aluminum oxide, dysprosium scandium oxide, and a combination thereof. However, embodiments of the present disclosure are not necessarily limited thereto.

In some embodiments, the channel structures CH may be arranged in a zigzag fashion. For example, as illustrated in FIG. 6, the channel structures CH may be arranged in a staggered manner in the first and second directions X and Y. Channel structures CH arranged in a zigzag fashion can further increase the integration density of the semiconductor memory device. In some embodiments, the channel structures CH may be arranged in a honeycomb fashion.

In some embodiments, the information storage films 132 may be formed as multilayer films. For example, referring to FIG. 8, the information storage films 132 may include tunnel insulating films 132a, charge storage films 132b, and blocking insulating films 132c, which are sequentially stacked on the outer side surfaces of the semiconductor patterns 130.

In an embodiment, the tunnel insulating films 132a may include, for example, silicon oxide or a high-k material (e.g., aluminum oxide (Al₂O₃) or hafnium oxide (HfO₂)) having a larger dielectric constant than silicon oxide. The charge storage films 132b may include, for example, silicon nitride. The blocking insulating films 132c may include, for example, silicon oxide or a high-k (e.g., Al₂O₃ or HfO₂) having a larger dielectric constant than silicon oxide.

In some embodiments, the channel structures CH may further include filler patterns 134. The filler patterns 134 may be formed to fill the inside of the semiconductor patterns 130, which is cup-shaped. In an embodiment, the filler patterns 134 may include an insulating material such as, for example, silicon oxide. However, embodiments of the present disclose disclosure are not necessarily limited thereto.

In some embodiments, the channel structures CH may further include channel pads 136. The channel pads 136 may be formed to be connected to the semiconductor patterns 130. For example, the channel pads 136 may be formed in a first interlayer insulating film 140a to be connected to the tops of the semiconductor patterns 130. In an embodiment, the channel pads 136 may include, for example, polysilicon doped with impurities. However, embodiments of the present disclosure are not necessarily limited thereto.

In some embodiments, the first source structure 105 may be formed on the cell substrate 100. The first source structure 105 may be interposed between the cell substrate 100 and the first stack structure ST1 (e.g., in the third direction Z). For example, the first source structure 105 may extend along the first surface 100S1 of the cell substrate 100. The cell array structure CS may include the cell substrate 100 and the first source structure 105 sequentially stacked (e.g., in the third direction Z) on the peripheral logic structure PS. For example, the first source structure 105 and the cell substrate 100 may extend by different lengths in the first direction X and/or the second direction Y and may thus have a step difference with each other. Thus, at least part of the first surface 100S1 of the cell substrate 100 may be exposed by the first source structure 105. However, embodiments of the present disclosure are not necessarily limited thereto. For example, in an embodiment, the first source structure 105 and the cell substrate 100 may extend by the same length in the first direction X and/or the second direction Y.

At least part of the first surface 100S1 of the cell substrate 100 may not be exposed by the first source structure 105. Alternatively, the cell substrate 100 may not protrude beyond the first source structure 105.

The first source structure 105 may be formed to be connected to the semiconductor patterns 130 of the channel structures CH. For example, as illustrated in FIG. 8, the first source structure 105 may be in direct contact with the semiconductor patterns 130 of the channel structures CH through the information storage films 132 of the channel structures CH. The first source structure 105 may be provided as, for example, the common source line CSL of FIG. 3. In an embodiment, the first source structure 105 may include polysilicon doped with impurities or a metal. However, embodiments of the present disclosure are not necessarily limited thereto.

In some embodiments, the channel structures CH may penetrate the first source structure 105. For example, the bottoms of the channel structures CH may be buried in the cell substrate 100 through the first source structure 105.

In some embodiments, the first source structure 105 may be formed as a multifilm. For example, the first source structure 105 may include first and second source layers 102 and 104, which are sequentially stacked on the cell substrate 100, In an embodiment, the first and second source layers 102 and 104 may include polysilicon doped or not doped with impurities. The first source layer 102 may be in contact with the semiconductor patterns 130 of the channel structures CH and may thus be provided as, for example, the common source line CSL of FIG. 3. The second source layer 104 may be used as a support layer for preventing the collapse of a mold stack during a replacement process for forming the first source layer 102.

In an embodiment, a base insulating film may be interposed between the cell substrate 100 and the first source structure 105. In an embodiment, the base insulating film may include at least one of, for example, silicon oxide, silicon nitride, and silicon oxynitride. However, embodiments of the present disclosure are not necessarily limited thereto.

A filler insulating film 101 may be formed on the peripheral logic structure PS. In an embodiment, the filler insulating film 101 may include, for example, silicon oxide. However, embodiments of the present disclosure are not necessarily limited thereto.

A first interlayer insulating film 141 may be formed on the filler insulating film 101. The first interlayer insulating film 141 may cover the first stack structure ST1. In an embodiment, the first interlayer insulating film 141 may include at least one of, for example, silicon oxide, silicon oxynitride, and a low-k material having a smaller dielectric constant than silicon oxide, However, embodiments of the present disclosure are not necessarily limited thereto. A second interlayer insulating film 142 may be formed on the first interlayer insulating film 141.

The bitlines BL may be formed on the first stack structure ST1. For example, the bitlines BL may be formed on the second interlayer insulating film 142.

The bitlines BL may intersect the block separation structures WLC. For example, the bitlines BL may intersect the third direction Z in parallel to the first surface 100S1 of the cell substrate 100) and may extend in the first direction X, which intersects the second direction Y.

The bitlines BL may be connected to the channel structures CH For example, bitline contacts 170, which are connected to the top surfaces of the channel structures CH through the first and second interlayer insulating films 141 and 142, may be formed. The bitlines BL may be electrically connected to the channel structures CH through the bitline contacts 170.

The first gate electrodes 120 may be connected to gate contacts 152, in the extension region EXT. For example, the gate contacts 152. may be connected to the first gate electrodes 120, which form the staircase structure STS, through the first and second interlayer insulating films 141 and 142.

The first source structure 105 may be connected to a source contact 154. For example, the source contact 154 may be connected to the first source structure 105 through the first and second interlayer insulating films 141 and 142.

The gate contacts 152 and/or the source contact 154 may be connected to upper wires 180 on the second interlayer insulating film 142. The upper wires 180 may be electrically connected to the first gate electrodes 120 through the gate contacts 152 and may be electrically connected to the first source structure 105 through the source contact 154.

The peripheral logic structure PS may be formed on the cell array structure CS. The peripheral logic structure PS may be formed on the second surface 100S2 of the cell substrate 100.

The peripheral logic structure PS may include a peripheral logic substrate 200, a device isolation film 202, peripheral transistors PTR, a lower wiring structure IS, and the bypass vias 310 and 320.

In an embodiment, the peripheral logic substrate 200 may be a bulk silicon substrate or a SOI substrate. However, embodiments of the present disclosure are not necessarily limited thereto. For example, in an embodiment the peripheral logic substrate 200 may be a silicon (Si) substrate or may include a material other than Si, such as, for example, silicon germanium (SiGe), SiGe-on-insulator (SGOI), indium antimonide, lead tellurium compound, indium arsenide, indium phosphide, gallium arsenide, or gallium antimonide.

The device isolation film 202 may be formed on the peripheral logic substrate 200. The peripheral logic substrate 200 may include active regions, which are defined by the device isolation film 202.

The peripheral transistors PTR may be formed on the active regions of the peripheral logic substrate 200. The peripheral transistors PTR may form the row decoder 33, the page buffer 35, and the control logic 37 of FIG. 1 and the first through fourth pass transistors PT1 through PT4 of FIG. 4, which are included in the row decoder 33.

The peripheral logic structure PS may include a peripheral logic insulating film 240 formed on the peripheral logic substrate 200. The peripheral logic insulating film 240 may cover the peripheral transistors PTR. In an embodiment, the peripheral logic insulating film 240 may include at least one of, for example, silicon oxide, silicon nitride, and silicon oxynitride.

The lower wiring structure IS may be formed on the peripheral logic substrate 200. The lower wiring structure IS may be connected to the peripheral transistors PTR, in the peripheral logic insulating film 240. The lower wiring structure IS may include a plurality of lower wires (LM1 through LM3) and a plurality of lower vias (LV1 through LV3). The lower wires (LM1 through LM3) may be connected to one another through the lower vias (LV1 through LV3). The number of lower wires (LM1 through LM3) is not particularly limited to those shown in an embodiment of FIG. 7 and may vary.

The lower wiring structure IS may be connected to the peripheral transistors PTR through a through plug 156. The through plug 156 may penetrate the first and second interlayer insulating films 141 and 142, the filler insulating film 101, and the peripheral logic insulating film 240 to connect the upper wires 180 and the lower wiring structure IS. Accordingly, the bitlines BL, the first gate electrodes 120, and/or the first source structure 105 may be electrically connected to the peripheral transistors PTR.

In some embodiments, referring to FIGS. 5, 7, and 9, the semiconductor memory device may include the bypass vias 310 and 320. The bypass vias 310 and 320 may electrically connect the cell substrate 100 and the peripheral logic substrate 200. The bypass vias 310 and 320 may disposed in the peripheral logic insulating film 240. For example, the bypass vias 310 and 320 may extend from a direction from the peripheral logic substrate toward the cell substrate. For example, the bypass vias 310 and 320 may penetrate the peripheral logic insulating film 240 to connect the cell substrate 100 and the peripheral logic substrate 200 to each other. For example, each of the bypass vias 310 and 320 may include a plurality of vias stacked in the direction from the peripheral logic substrate toward the cell substrate. The bypass vias 310 and 320 may be in direct contact with (e.g., directly connected to), for example, the cell substrate 100 and the peripheral logic substrate 200. The bypass vias 310 and 320 may be in direct contact with the second surface 100S2 the cell substrate 100. In some embodiments, the width of the bypass vias 310 and 320 may increase as the distance from the peripheral logic substrate 200 increases. However, embodiments of the present disclosure are not necessarily limited thereto. For example, in some embodiments, the width of the bypass vias 310 and 320 may be substantially uniform regardless of the distance from the peripheral logic substrate 200.

In an embodiment, channel holes for forming the channel structures CH may be formed by an anisotropic etching process using high-energy plasma. In this embodiment, a positive charge may accumulate in the first source structure 105 (e.g., in the first source layer 102) and may thus cause arching. However, since the positive charge accumulated in the first source structure 105 during the formation of the channel holes can be released into the peripheral logic substrate 200 through the bypass vias 310 and 320, arching can be prevented.

The bypass vias 310 and 320 may be disposed on a first side and/or an opposite second side (e.g., in the first direction X) of the stack structure ST. The number and the size of bypass vias 310 and 320 and the distance between the bypass vias 310 and 320 may vary. For example, in an embodiment the size of the bypass vias 310 and 320 on the cell substrate 100 may be determined by the amount of positive charge accumulated in the first source structure 105 during the formation of the channel holes.

In a comparative embodiment in which the bypass vias 310 and 320 have a hole shape and are arranged in the first direction X and/or the second direction Y, the size of the space in which to arrange the peripheral transistors PTR, the lower wiring structure IS, and/or the upper wires 180 may be limited by the size of an area in which to form the bypass vias 310 and 320.

Referring to FIG. 5, in an embodiment the bypass vias 310 and 320 may have a linear or bar shape. For example, the bypass vias 310 and 320 may extend in the first direction X and/or the second direction Y and may be formed on the cell substrate 100 as bars having a rectangular cross-sectional shape. The first and second directions X, Y may be parallel to an upper surface of the cell substrate 100. However, embodiments of the present disclosure are not necessarily limited thereto. For example, in an embodiment, the bypass vias 310 and 320 may be formed as bars extending in a direction between the first and second directions X and Y and parallel to an upper surface of the cell substrate 100. The bypass vias 310 and 320 may have a predetermined area on the cell substrate 100 and may have a linear or bar shape.

In an embodiment in which the bypass vias 310 and 320 have a linear or bar shape, no gaps may be formed between the bypass vias 310 and 320, as compared to an embodiment in which the bypass vias 310 and 320 have a hole shape. Also, the bypass vias 310 and 320 may have a larger area when having a square shape than when having a hole shape, even if the length of the square shape is the same as the diameter of the hole shape. Thus, as the area of the bypass vias 310 and 320 on the cell substrate 100 can be reduced, space in which to arrange the peripheral transistors PTR, the lower wiring structure IS, and/or the upper wires 180 can be further widened. In addition, as the bypass vias 310 and 320 have a predetermined area, arching can be prevented.

In some embodiments, the bypass vias 310 and 320 may be disposed on both sides of the stack structure ST. For example, first bypass vias 310 may be disposed on a first side (e.g., in the first direction X) of the stack structure ST, and a second bypass via 320 may be disposed on the opposite second side (e.g., in the first direction X) of the stack structure ST. In an embodiment, the first bypass vias 310 and the second bypass via 320 may have a linear or bar shape extending in the second direction Y.

In some embodiments, the number of first bypass vias 310 and the number of second bypass vias 320 may differ from each other. For example, the first bypass vias 310 may include (1-1)-th and (1-2)-th bypass vias 311 and 312, which are spaced apart from each other. The (1-1)-th and (1-2)-th bypass vias 311 and 312 may be spaced apart from each other in the first direction X.

Widths W11 and W12 (e.g., lengths in the first direction X) of the first bypass vias 310 and lengths L11 and L12 (e.g., lengths in the second direction Y), of the first bypass vias 310 may be determined by the area of the first bypass vias 310 on the cell substrate 100, and widths W21 and W22 (e.g., lengths in the first direction X) of the second bypass via 320 and lengths L21 and L22 (e.g., lengths in the second direction Y) of the second bypass via 320 may be determined by the area of the second bypass via 320 on the cell substrate 100. The bypass vias 310 and 320 may have a predetermined area on the cell substrate 100 and may have various sizes or shapes. For example, bypass vias 310 and 320 having a linear shape and having the same total area as a number of bypass vias having a hole shape can be obtained by controlling the width (e.g., length in the first direction X) of the bypass vias while maintaining the length (e.g., length in the second direction Y) of the bypass vias.

In some embodiments, the width W11 (e.g., length in the first direction X), of the (1-1)-th bypass via 311 may differ from the width W12 (e.g., length in the first direction X) of the (1-2)-th bypass via 312. For example, in an embodiment the width W11 of the (1-1)-th bypass via 311 may be less than the width W12 of the (1-2)-th bypass via 312. In some embodiments, the width W11 (e.g., length in the first direction X) of the (1-1)-th bypass via 311 may differ from the width W13 (e.g., length in the first direction X) of the second bypass via 320. For example, in an embodiment the width W11 of the (1-1)-th bypass via 311 may be less than the width W13 of the second bypass via 320. For example, the width W13 of the second bypass via 320 may be substantially the same as the width W12 of the (1-2)-th bypass via 312.

In some embodiments, the length L11 (e.g., length in the second direction Y) of the (1-1)-th bypass via 311, the length L12 (e.g., length in the second direction Y) of the (1-2)-th bypass via 312, and the length L13 (e.g., length in the second direction Y) of the second bypass via 320 may all be the same on the cell substrate 100.

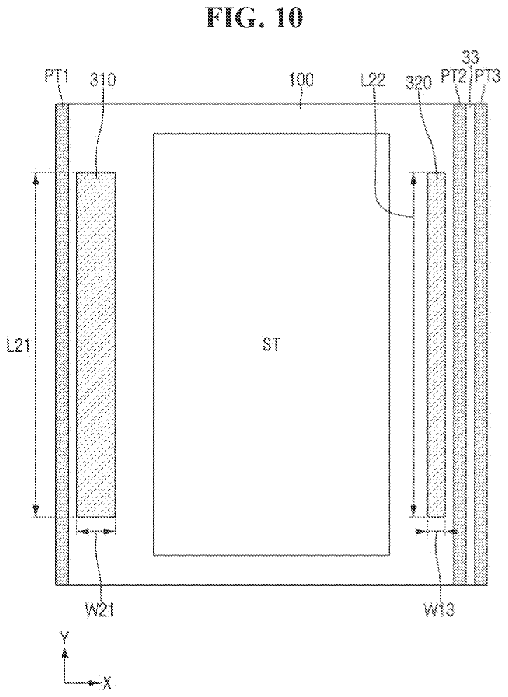

FIGS. 10 through 17 illustrate semiconductor memory devices according to some embodiments of the present disclosure. For convenience, the embodiments of FIGS. 10 through 17 will hereinafter be described, focusing mainly on the differences with the embodiments of FIGS. 1 through 9.

Referring to FIG. 10, the semiconductor memory device may include one first bypass via 310 and one second bypass via 320. The first and second bypass vias 310 and 320 may extend in a second direction Y and may have a linear shape.

For example, bypass vias 310 and 320 having a linear shape and having the same total area as bypass vias having a hole shape can be formed by omitting any gaps, in the first direction X and the second direction Y, between the bypass vias having the hole shape.

In some embodiments, a width W21 (e.g., length in the first direction X) of the first bypass via 310 may differ from a width W22 (e length in the first direction X) of the second bypass via 320. For example, in an embodiment the width W21 of the first bypass via 310 may be greater than the width W22 of the second bypass via 320.

In some embodiments, a length L21 (e.g., length in the second direction Y) of the first bypass via 310 may be the same as a length L22 (e.g., length in the second direction Y) of the second bypass via 320.

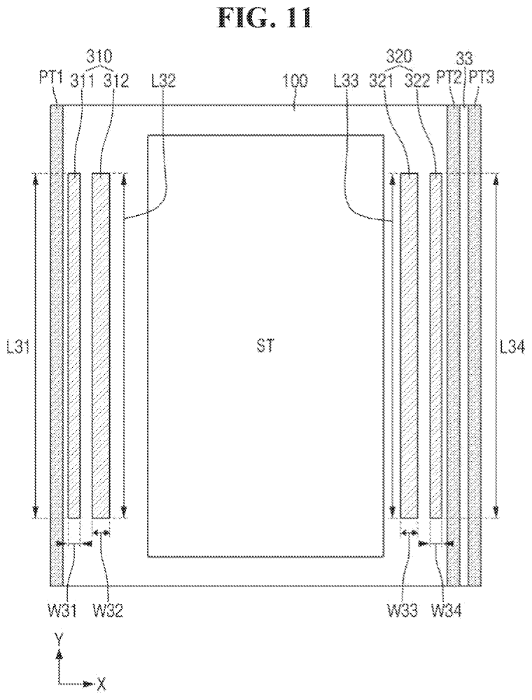

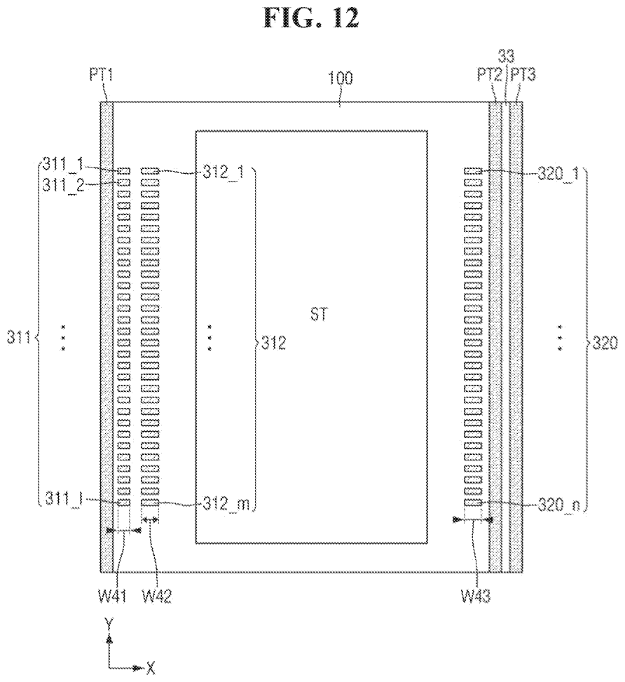

Referring to FIG. 11, the number of first bypass vias 310 may be the same as the number of second bypass vias 320.

In some embodiments, the first bypass vias 310 may be symmetrical with the second bypass vias 320 with respect to a stack structure ST. For example, a width W31 (e.g., length in a first direction X) of a (1-1)-th bypass via 311 may be the same as a width W34 (e.g., length in the first direction X) of a (2-2)-th bypass via 322, and a width W32 (length in the first direction X) of a (1-2)-th bypass via 312 may be the same as a width W33 (e.g., length in the first direction X) of a (2-1)-th bypass via 321, Lengths L31 and L32 (e,g., lengths in the second direction Y) of the first bypass vias 310 may be the same as lengths L33 and L34 (e.g., lengths in the second direction Y) of the second bypass vias 320.

In some embodiments, the width W31 (e.g., length in the first direction X) of the (1-1)-th bypass via 311 may be the same as the width W33 (e.g., length in the first direction X) of the (2-1)-th bypass via 321, and the width W32 (e.g., length in the first direction X) of the (1-2)-th bypass via 312 may be the same as the width W34 (e.g., length in the first direction X) of the (2-2)-th bypass via 322.

Referring to FIG. 12, first bypass vias and second bypass vias 320 may have a linear shape extending in a first direction X.

For example, bypass vias 310 and 320 having a linear shape and having the same total area as bypass vias having a hole shape can be formed by omitting any gaps, in the first direction X, between the bypass vias having the hole shape.

The first bypass via 310 may include a plurality of (1-1)-th bypass vias (311_1 through 311_1 where l is a natural number) and a plurality of (1-2)-th bypass vias (312_1 through 312_m where m is a natural number). The (1-1)-th bypass vias (311_1 through 311_I) and the (1-2)-th bypass vias (312_1 through 312_m) may be spaced apart from one another in the first direction X. The second bypass vias 320 may include a plurality of second bypass vias (320_1 through 320_n where n is a natural number), which are arranged in a second direction Y. In embodiments, the natural numbers l, m, and n may be the same or may differ from one another. For example, in an embodiment, m may be greater than n.

In some embodiments, a width W41 (e.g., length in the first direction X) of the (1-1)-th bypass via 311 may differ from a width W43 (e.g., length in the first direction X) of the second bypass vias 320. For example, the width W41 of the (1-1)-th bypass vias (311_1 through 311_I) may be less than the width W43 of the second bypass vias 320, For example, in an embodiment a width W43 (e.g., length in the first direction X) of the second bypass vias 320 may be substantially the same as a width W42 (e.g., length in the first direction X) of the (1-2)-th bypass vias (312_1 through 312_m).

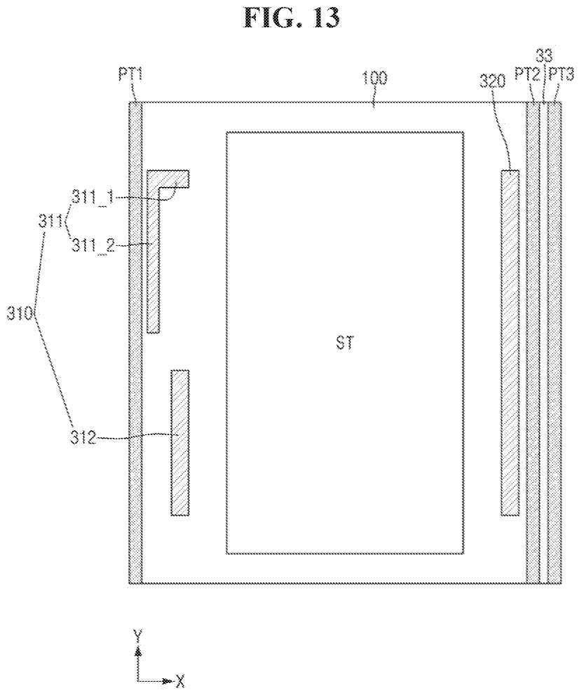

Referring to FIG. 13, a (1-1)-th bypass via 311 may include a first portion 311_1, which extends in the first direction X, and a second portion 311_2, which extends in the second direction Y. The second portion 311_2 may be connected to one end of the first portion 311_1. For example, the (1-1)-th bypass via 311 may have an L shape that is symmetrical in the second direction Y, on a cell substrate 100. However, embodiments of the present disclosure are not necessarily limited thereto. For example, in an embodiment, the (1-1)-th bypass via 311 may have an L shape or an L shape that is symmetrical in the second direction Y. In some embodiments, a (1-2)-th bypass via 312 and a second bypass via 320 may have a linear shape extending in the second direction Y, on the cell substrate 100.

Alternatively, the (1-2)-th bypass via 312 and the second bypass via 320 may have an L shape, an L shape that is symmetrical in the first direction X, or an L shape that is symmetrical in the first and second directions X and Y, on the cell substrate 100.

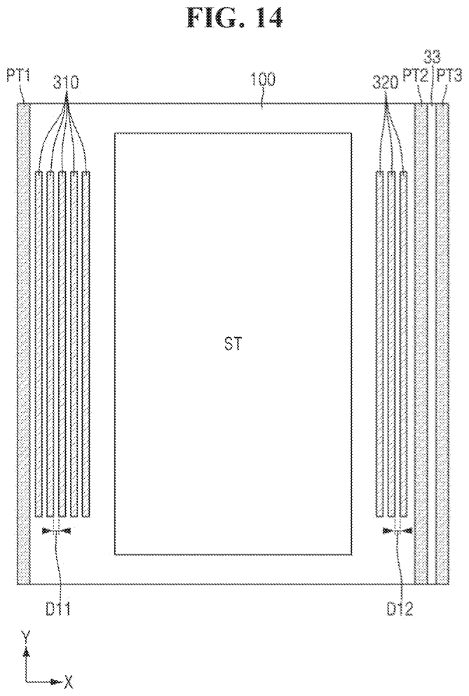

Referring to FIG. 14, a plurality of first bypass vias 310 and a plurality of second bypass vias 320 may be provided and may extend in the second direction Y.

For example, bypass vias 310 and 320 having a linear shape and having the same total area as bypass vias having a hole shape can be formed by omitting any gaps, in the second direction Y, between the bypass vias having the hole shape.

For example, a distance D11 between the first bypass vias 310 may be substantially the same as, or different from, a distance D12. between the second bypass vias 320. Also, the distance D11 between the first bypass vias 310 and/or the distance D12 between the second bypass vias 320 may not be uniform.

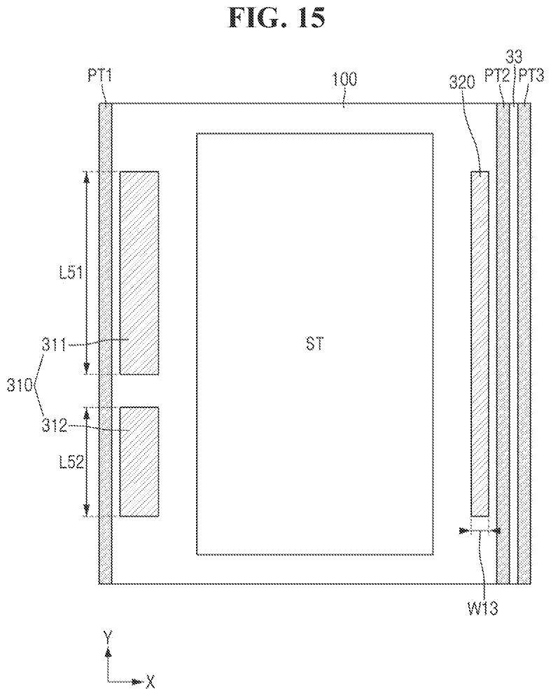

Referring to FIG. 15, first bypass vias 310 may include (1-1)-th and 1-2)-th bypass vias 311 and 312, which extend in a second direction Y and are spaced apart from each other in the second direction Y.

For example, in an embodiment a length L51 (e.g., length in the second direction Y) of the (1-1)-th bypass via 311 may differ from a length L52 (e.g., length in the second direction Y) of the (1-2)-th bypass via 312.

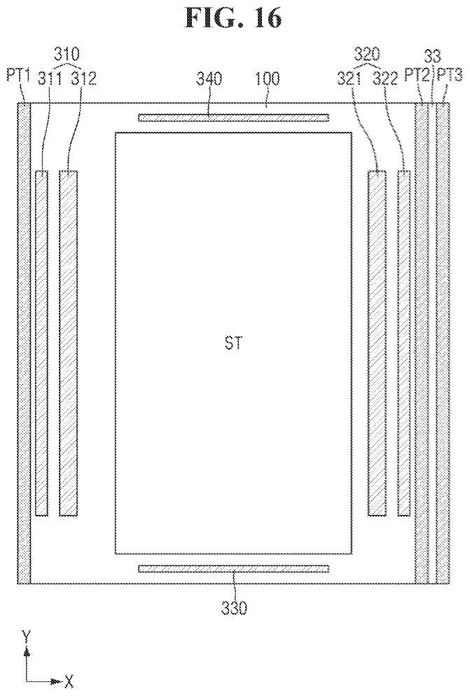

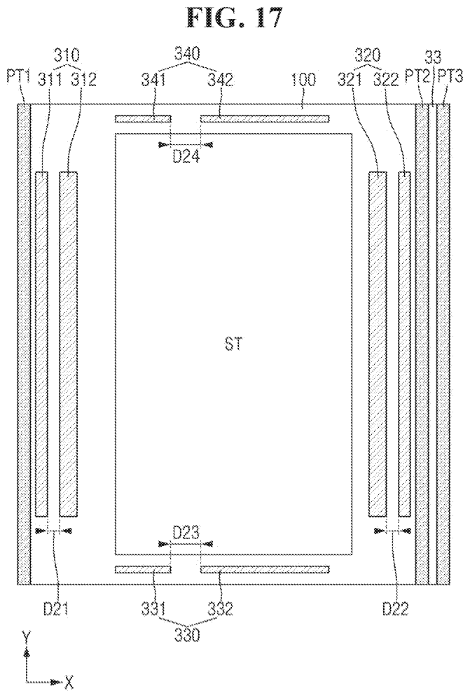

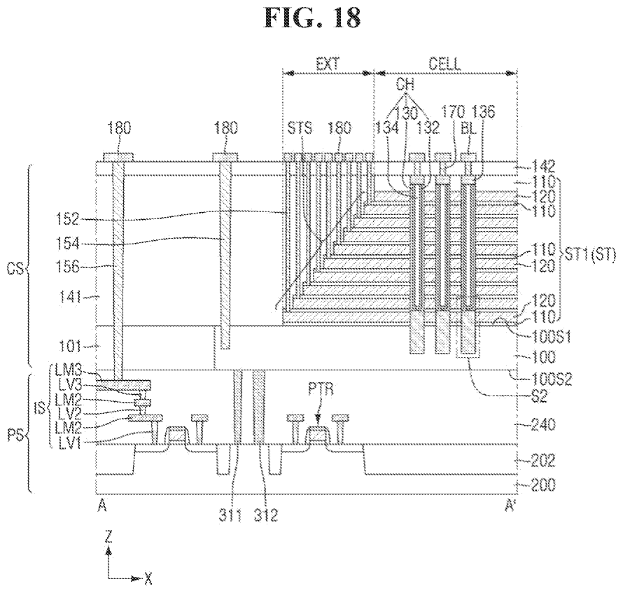

FIGS. 16 and 17 illustrate semiconductor memory devices according to some embodiments of the present disclosure. For convenience, the embodiments of FIGS. 16 and 17 will hereinafter be described, focusing mainly on the differences with the embodiment of FIG. 11.

Referring to FIGS. 16 and 17, the semiconductor memory devices may further include third and fourth bypass vias 330 and 340. The third and fourth bypass vias 330 and 340 may have a predetermined area on a cell substrate 100 and may have a linear shape. For example, in an embodiment the third and fourth bypass vias 330 and 340 may have a linear shape extending in a first direction X, on the cell substrate 100.

One or more third bypass vias 330 may be disposed on a first side (e.g., in the second direction Y) of a stack structure ST, and one or more fourth bypass vias 340 may be disposed on the opposite second side (e.g., in the second direction Y) of the stack structure ST. In some embodiments, the third bypass vias 330 may be symmetrical with the fourth bypass vias 340 with respect to the stack structure ST.

In some embodiments, first and second bypass vias 310 and 320 may have a larger area than the third and fourth bypass vias 330 and 340, on the cell substrate 100.

Referring to FIG. 16, in some embodiments, the numbers of third bypass vias 330 and fourth bypass vias 340 may be less than the numbers of first bypass vias 310 and second bypass vias 320.

Referring to FIG. 17, the numbers of third bypass vias 330 and fourth bypass vias 340 may be the same as the numbers of first bypass vias 310 and second bypass vias 320.

In an embodiment, a distance D21 between the first bypass vias 310 and a distance D22 between the second bypass vias 320 may be less than a distance D23 between the third bypass vias 330 and a distance D24 between the fourth bypass vias 340.

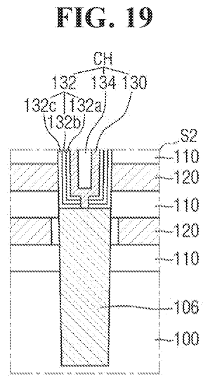

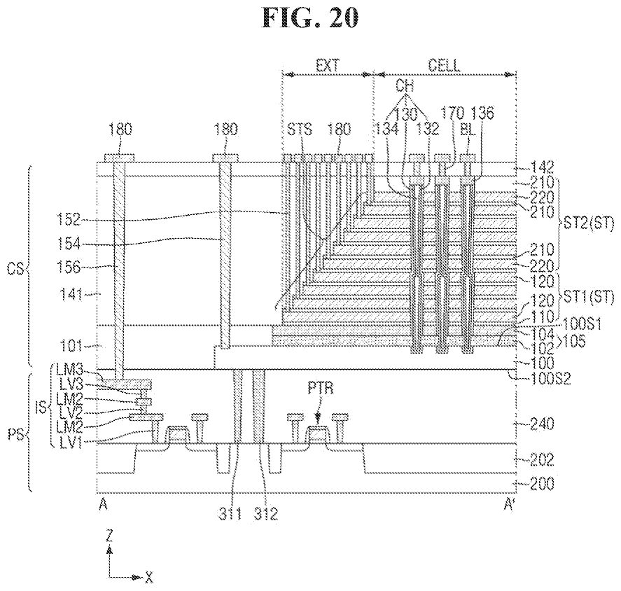

FIGS. 18 and 20 are cross-sectional views, taken along line A-A′ of FIG. 5, of semiconductor memory devices according to some embodiments of the present disclosure. FIG. 19 is an enlarged cross-sectional view of an area S2 of FIG. 18. For convenience, the embodiments of FIGS. 18 through 20 will hereinafter be described, focusing mainly on the differences with the embodiments of FIGS. 1 through 9.

Referring to FIGS. 18 and 19, the semiconductor memory device include a second source structures 106.

The second source structures 106 may be formed on a cell substrate 100. Lower parts of the second source structures 106 may be buried in the cell substrate 100. However, embodiments of the present disclosure are not necessarily limited thereto. The second source structures 106 may be connected to semiconductor patterns 130 of channel structures CH. For example, the semiconductor patterns 130 may be in direct contact with the top surfaces of the second source structures 106 through information storage films 132. In an embodiment, the second source structures 106 may be formed from the cell substrate 100 by, for example, a selective epitaxial growth process. However, embodiments of the present disclosure are not necessarily limited thereto.

In some embodiments, the top surfaces of the second source structures 106 may intersect some of first gate electrodes 120. For example, the top surfaces of the second source structures 106 may be formed to be higher than the top surface of a lowermost first gate electrode 120. In this embodiment, gate insulating films may be interposed between the second source structures 106 and the first gate electrodes 20 that are intersected by the second source structures 106.

Referring to FIG. 20, the semiconductor memory device may further include a second stack structure ST2.

The second stack structure ST2 may be formed on a first stack structure ST1. The second stack structure ST2 may include a plurality of second gate electrodes 220 and a plurality of second insulating films 210, which are alternately stacked on the cell substrate 100. The second gate electrodes 220 and the second insulating films 210 may have a layered structure extending in parallel to a first surface 100S1 of the cell substrate 100. The second gate electrodes 220 and the second insulating films 210 may be alternately stacked on the cell substrate 100 (e.g., in the third direction Z). The number of second gate electrodes 220 is not particularly limited, but may vary.

In an embodiment, the first gate electrodes 120 may correspond to the erase control line ECL, the ground selection lines GSL, the wordlines (WL11 through WL1n), and the string selection lines SSL of FIG. 3, and the second gate electrodes 220 may correspond to the wordlines (WL21 through WL2n) and the string selection lines SSL of FIG. 3. In some embodiments, second gate electrodes 220 adjacent to the string selection lines SSL may be dummy gate electrodes.

A first interlayer insulating film 141 may cover the second stack structure ST2.

The channel structures CH may penetrate the first and second stack structures ST1 and ST2. In some embodiments, the width of the channel structures CH in the first and second stack structures ST1 and ST2 may increase as a distance from the cell substrate 100 increases. In some embodiments, the channel structures CH may have bent portions between the first and second stack structures ST1 and ST2 due to the characteristics of an etching process for forming the channel structures CH. However, embodiments of the present disclosure are not necessarily limited thereto.

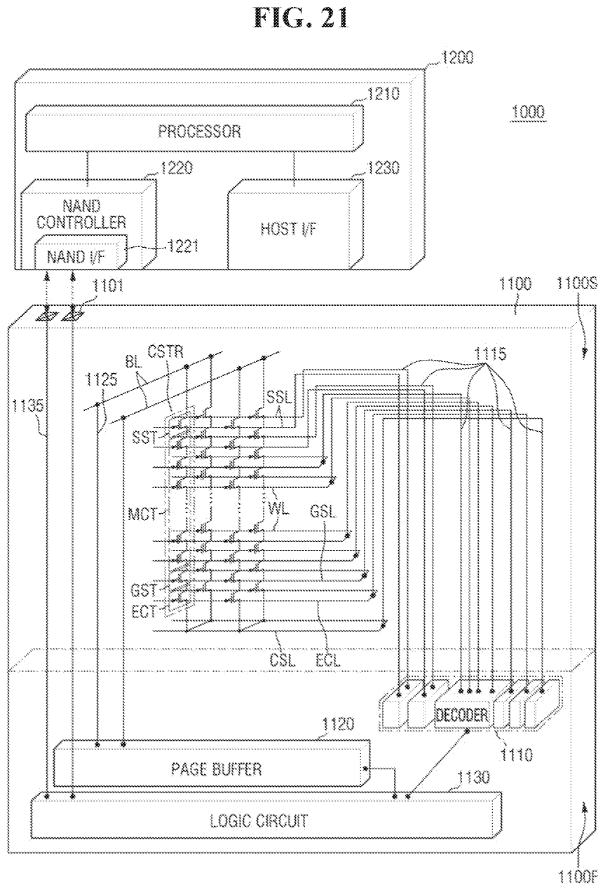

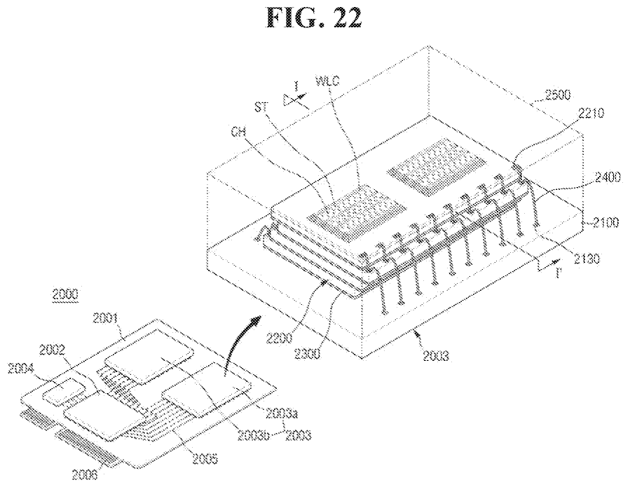

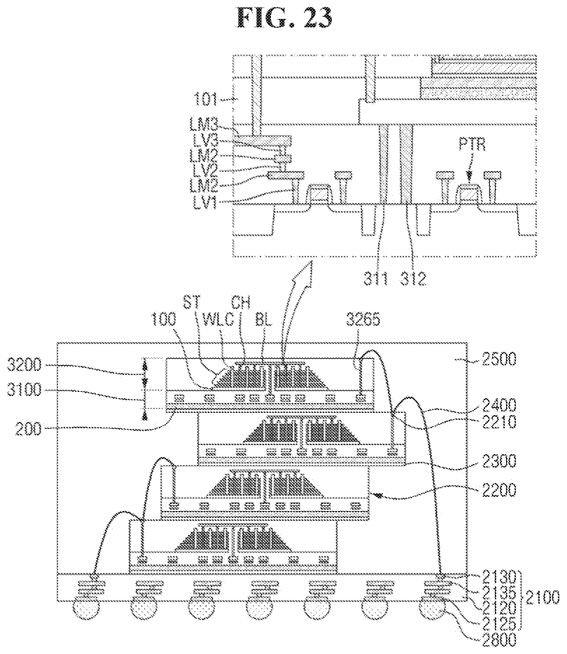

FIG. 21 illustrates an electronic system including a semiconductor memory device according to an embodiment of the present disclosure. FIG. 22 illustrates an electronic system including a semiconductor memory device according to an embodiments of the present disclosure. FIG. 23 is a cross-sectional view taken along line I-I′ of FIG. 22.

Referring to FIG. 21, an electronic system 1000 may include a semiconductor memory device 1100 and a controller 1200, which is electrically connected to the semiconductor memory device 1100. In an embodiment, the electronic system 1000 may be a storage device including at least one semiconductor memory device 1100 or an electronic device including a storage device. For example, the electronic system 1000 may be a solid-state drive (SSD) device, a universal serial bus (USB), a computing system, medical equipment, or a communication device including at least one semiconductor memory device 1100. However, embodiments of the present disclosure are not necessarily limited thereto.

The semiconductor memory device 1100 may be a nonvolatile memory device and may correspond to, for example, the NAND flash memory device of FIG. 20. The semiconductor memory device 1100 may include a first structure 1100F and a second structure 1100S on the first structure 1100F.

The first structure 1100F may be a peripheral circuit structure including a decoder circuit 1110 (e.g., the row decoder 33 of FIG. 1), a page buffer 1120 (e.g., the page buffer 35 of FIG. 1), and a logic circuit 1130 (e.g., the control logic 37 of FIG. 1).

The second structure 1100S may include a common source line CSL, a plurality of bitlines BL, and a plurality of cell strings CSTR, as described above with reference to FIG. 3. The cell strings CSTR may be connected to the decoder circuit 1110 through wordlines WL, at least one string selection line SSL, and at least one ground selection line GSL. Also, the cell strings CSTR may be connected to the page buffer 1120 through the bitlines BL.

In some embodiments, the common source line CSL and the cell strings CSTR may be electrically connected to the decoder circuit 1110 through first connecting wires 1115, which extend from the first structure 1100F to the second structure 1100S. The first connecting wires 1115 may correspond to the through plug 156 of any one of FIGS. 1 through 20. For example, the through plug 156 may electrically connect gate electrodes (ECL, GSL, WL, and SSL) and the decoder circuit 1110 (or the row decoder 33 of FIG. 1).

In some embodiments, the bitlines BL may be electrically connected to the page buffer 1120 through second connecting wires 1125, which extend from the first structure 1100F to the second structure 1100S. The second connecting wires 1125 may correspond to the through plug 156 of any one of FIGS. 1 through 20. For example, the through plug 156 may electrically connect the bitlines BL and the page buffer 1120 (or the page buffer 35 of FIG. 1),

The semiconductor memory device 1100 may communicate with the controller 1200 through input/output pads 1101, which are electrically connected to the logic circuit 1130 (or the control logic 37 of FIG. 1). The input/output pads 1101 may be electrically connected to the logic circuit 1130 through input/output connecting wires 1135, which extend from the first structure 1100F to the second structure 1100S.

In an embodiment, the controller 1200 may include a processor 1210, a NAND controller 1220, and a host interface 1230. In some embodiments, the electronic system 1000 may include a plurality of semiconductor memory devices 1100, in which case, the controller 1200 may control the plurality of semiconductor memory devices 1100.

The processor 1210 may control the general operation of the electronic system 1000 including the controller 1200. The processor 1210 may operate in accordance with predetermined firmware and may access the semiconductor memory device 1100 by controlling the NAND controller 1220. The NAND controller 1220 may include a NAND interface 1221, which handles communication with the semiconductor memory device 1100. Control commands for controlling the semiconductor memory device 1100, data to be written to memory cell transistors MCT of the semiconductor memory device 1100, and data to be read from the memory cell transistors MCT of the semiconductor memory device 1100 may be transmitted through the NAND interface 1221. The host interface 1230 may provide communication between the electronic system 1000 and an external host. In response to a control command being received from an external host through the host interface 1230, the processor 1210 may control the semiconductor memory device 1100 in accordance with the received control command.

Referring to FIGS. 21 through 23, an electronic system 2000 may include a main substrate 2001, a main controller 2002, which is mounted on the main substrate 2001, one or more semiconductor packages 2003, and a dynamic random access memory (DRAM) 2004, The semiconductor packages 2003 and the DRAM 2004 may be connected to the main controller 2002 by wire patterns 2005, which are formed on the main substrate 2001.

The main substrate 2001 may include a connector 2006, which includes a plurality of pins that can be coupled to an external host. The number and layout of pins of the connector 2006 may vary depending on the type of communication interface between the electronic system 2000 and the external host. In some embodiments, the electronic system 2000 may communicate with the external host using one of the following interfaces: USB, Peripheral Component Interconnect-Express (PCI-Express), Serial Advanced Technology Attachment (BATA), M-PHY for Universal Flash Storage (UFS). However, embodiments of the present disclosure are not necessarily limited thereto. In some embodiments, the electronic system 2000 may be operable by power supplied from the external host through the connector 2006. The electronic system 2000 may further include a power management integrated circuit (PMIC), which divides the power from the external host between the main controller 2002 and the semiconductor packages 2003.

The main controller 2002 may write data to, or read data from, the semiconductor packages 2003 and may increase the operating speed of the electronic system 2000.

The DRAM 2004 may be a buffer memory for mitigating the difference between the speed of the semiconductor packages 2003, which are data storages, and the speed of the external host. The DRAM 2004, which is included in the electronic system 2000, may function as a type of cache memory and may provide space for temporarily storing data during a control operation for the semiconductor packages 2003. In an embodiment in which the DRAM 2004 is included in the electronic system 2000, the main controller 2002 may further include a DRAM controller for controlling the DRAM 2004 in addition to a NAND controller for controlling the semiconductor packages 2003.

The semiconductor packages 2003 may include first and second semiconductor packages 2003a and 2003b, which are spaced apart from each other. Each of the first and second semiconductor packages 2003a and 2003b may be a semiconductor package including multiple semiconductor chips 2200. Each of the first and second semiconductor packages 2003a and 2003b may include a package substrate 2100, semiconductor chips 2200 on the package substrate 2100, adhesive layers 2300, which are disposed on the bottom surfaces of the semiconductor chips 2200, connecting structures 2400, which electrically connect the semiconductor chips 2200 and the package substrate 2100, and a molding layer 2500, which covers the semiconductor chips 2200 and the connecting structures 2400 on the package substrate 2100.

The package substrate 2100 may be a printed circuit board including package upper pads 2130. Each of the semiconductor chips 2200 may include input/output pads 2210. The input/output pads 2210 may correspond to the input/output pads 1101 of FIG. 20.

In some embodiments, the connecting structures 2400 may be bonding wires that electrically connect the input/output pads 2210 and the package upper pads 2130. Thus, in each of the first and second semiconductor packages 2003a and 2003b, the semiconductor chips 2200 may be electrically connected to one another via wire bonding and may be electrically connected to the package upper pads 2130 of the package substrate 2100. In some embodiments, in each of the first and second semiconductor packages 2003a and 2003b, the semiconductor chips 2200 may be electrically connected to one another through connecting structures including through silicon vias (TSVs), instead of wire bonding-type connecting structures 2400.

In some embodiments, the main controller 2002 and semiconductor chips 2200 may be included in a single package. In some embodiments, the main controller 2002 and semiconductor chips 2200 may be mounted on an interposer substrate, which is separate from the main substrate 2001, and may be connected by wires that are formed on the interposer substrate.

In some embodiments, the package substrate 2100 of each of the first and second semiconductor packages 2003a and 2003b may be a printed circuit board. The package is substrate 2100 of each of the first and second semiconductor packages 2003a and 2003b may include a package substrate body 2120, package upper pads 2130, which are disposed on the top surface of the package substrate body 2120, lower pads 2125, which are disposed or exposed on the bottom surface of the package substrate body 2120, and inner wires 2135, which electrically connect the package upper pads 2130 and the lower pads 2125, in the package substrate body 2120. The package upper pads 2130 may be electrically connected to connecting structures 2400. The lower pads 2125 may be connected to the wire patterns 2005 of the main substrate 2010 of the electronic system 2000 through conductive connectors 2800, as illustrated in FIG. 22.

Referring to FIG. 23, each of the semiconductor chips 2200 may include a first peripheral circuit region 3100 and a first cell region 3200, which is stacked on the first peripheral circuit region 3100. Each of the semiconductor chips 2200 may include any one of the semiconductor memory devices of FIGS. 1 through 20. For example, the first peripheral circuit region 3100 may correspond to the peripheral logic structure PS of any one of FIGS. 1 through 20. Also, for example, the first cell region 3200 may correspond to the cell array structure CS of any one of FIGS. 1 through 20.

Embodiments of the present disclosure have been described above with reference to the accompanying drawings, but embodiments of the present disclosure are not necessarily limited thereto and may be implemented in various different forms. It will be understood that the present disclosure can he implemented in other specific forms without changing the technical spirit or gist of the present disclosure. Therefore, it should he understood that the embodiments set forth herein are illustrative in all respects and not limiting.

What is claimed is:

1. A semiconductor memory device comprising
a peripheral logic structure including a peripheral logic substrate and a peripheral logic insulating film on the peripheral logic substrate;
a cell array structure including a cell substrate and a source structure that are sequentially stacked on the peripheral logic structure; and
a bypass via electrically connecting the cell substrate and the peripheral logic substrate,
wherein the bypass via has a linear shape extending in at least one of first and second directions on the cell substrate, the first and second directions are parallel to an upper surface of the cell substrate.

2. The semiconductor memory device of claim I, wherein the bypass via has an L shape on the cell substrate.

3. The semiconductor memory device of claim 1, wherein:
the second direction is perpendicular to the first direction; and
the bypass via comprises a plurality of bypass vias, the plurality of bypass vias extend in the first direction and are arranged in the second direction.

4. The semiconductor memory device of claim 1, wherein the bypass via includes a first bypass via extending in the second direction, and a second bypass via extending in the second direction and spaced apart from the first bypass via in the first direction.

5. The semiconductor memory device of claim 4, wherein a width in the first direction of the first bypass via, differs from a width in the first direction of the second bypass via,

6. The semiconductor memory device of claim 4, wherein a length in the second direction of the first bypass via differs from a length in the second direction of the second bypass via.

7. The semiconductor memory device of claim 4, wherein:
the cell array structure includes a stack structure that includes a plurality of gate electrodes stacked on the cell substrate;
the first bypass via is disposed on a first side in the first direction of the stack structure; and
the second bypass via is disposed on a second side in the first direction of the stack structure, the second side is opposite to the first side.

8. The semiconductor memory device of claim 7, wherein:
the first bypass via includes n (1-1)-th bypass vias, wherein n is a natural number,
(1-1)-th bypass vias extend in the second direction and are spaced apart from one another in the first direction; and
the second bypass via includes m (2-1)-th bypass vias, wherein m is a natural number greater than n, the (2-1)-th bypass vias extend in the second direction and are spaced apart from one another in the first direction.

9. The semiconductor memory device of claim 4, wherein:
the cell array structure includes a stack structure that includes a plurality of gate electrodes stacked on the cell substrate,
the bypass via further includes a third bypass via that is disposed on one side in the second direction of the stack structure, and
the first bypass via and the second bypass via are disposed on at least one side in the first direction of the stack structure.

10. The semiconductor memory device of claim 9, wherein:
the bypass via further includes a fourth bypass via disposed on the one side in the second direction of the stack structure and is spaced apart from the third bypass via in the first direction;
the first bypass via and the second bypass via are disposed on one side in the first direction of the stack structure; and
a distance in the first direction between the first bypass via and the second bypass via is less than a distance in the first direction between the third bypass via and the fourth bypass via.

11. The semiconductor memory device of claim 9, wherein a sum of an area of the first bypass via and an area of the second bypass via is greater than an area of the third bypass via.

12. The semiconductor memory device of claim 1, wherein the bypass via includes a first bypass via extending in the first direction, and a second bypass via extending in the first direction and spaced apart from the first bypass via in the first direction.

13. The semiconductor memory device of claim 12, wherein a length in the first direction of the first bypass via differs from a length in the first direction of the second bypass via.

14. The semiconductor memory device of claim 1, wherein the bypass via is in direct contact with the cell substrate.

15. A semiconductor memory device comprising:
a peripheral logic structure including a peripheral logic substrate and a peripheral transistor on the peripheral logic substrate;
a cell substrate and a source structure sequentially stacked on the peripheral logic structure;
a first stack structure including a plurality first gate electrodes that are stacked on the source structure; and
a first bypass via and a second bypass via electrically connecting the cell substrate and the peripheral logic substrate,
wherein a width in a first direction of the first bypass via differs from a width in the first direction of the second bypass via.

16. The semiconductor memory device of claim 15, wherein the first bypass via and the second bypass via extend in a direction from the peripheral logic substrate toward the cell substrate.

7. The semiconductor memory device of claim 15, wherein the first bypass via and the second bypass via are spaced apart from sides of the first stack structure.

18. The semiconductor memory device of claim 15, wherein:
the first bypass via is spaced apart from a first side of the first stack structure; and
the second bypass via is spaced apart from a second side of the first stack structure that is opposite to the first side.

19. The semiconductor memory device of claim 15, wherein the width in the first direction of the first bypass via and the width in the first direction of the second bypass via increases as a distance from the peripheral logic substrate increases.

20. An electronic system comprising:
a main substrate;
a semiconductor memory device on the main substrate; and
a controller on the main substrate, the controller is electrically connected to the semiconductor memory device,
wherein
the semiconductor memory device includes:
a peripheral logic substrate,
a peripheral transistor that is electrically connected to the controller on the peripheral logic substrate,
a peripheral logic insulating film that covers the peripheral transistors,
a cell substrate on the peripheral logic insulating film,
a source structure on the cell substrate,
a stack structure on the source structure, the stack structure includes a plurality of gate electrodes that are stacked,
a channel structure that penetrates the stack structure, and
a first bypass via and a second bypass via electrically connecting the cell substrate and the peripheral logic substrate, and
the first bypass via and the second bypass via have a linear shape extending in at least one of first and second directions on the cell substrate, the first and second directions are parallel to an upper surface of the cell substrate.
